(19) United States
(12) Patent Application Publication
(10) Pub. No.: US 2026/0075915 A1
(43) Pub. Date: Mar. 12, 2026

(54) METHOD OF FORMING SEMICONDUCTOR DEVICE

(71) Applicant: NANYA TECHNOLOGY CORPORATION, New Taipei City (TW)

(72) Inventor: Ying-Cheng CHUANG, New Taipei City (TW)

(21) Appl. No.: 18/882,768

(22) Filed: Sep. 12, 2024

(51) Int. Cl. H01L 29/423; H01L 21/28; H10B 12/00

(52) U.S. Cl. CPC H10D 64/513; H10B 12/053; H10D 64/01304

(57) ABSTRACT

A method of forming a semiconductor device includes forming a first metal material lining a trench in a semiconductor substrate at a first temperature. The method further includes forming a second metal material lining the first metal material at a second temperature higher than the first temperature. The method further includes performing an annealing process to the first and second metal materials.

### BACKGROUND

### Field of Invention

The present disclosure relates to a method of forming a semiconductor device.

### Description of Related Art

As the integration density of semiconductor devices increases, distances between features have gradually decreased. In turn, in integrated circuit (IC) fabrication, the critical dimensions of active areas have been scaled down. However, some issues of manufacturing the semiconductor devices may arise from the scaling down process. For example, residual stress accumulated around an interface of deposited layers may cause line wiggling and distortion of patterns.

Accordingly, how to provide a method of forming a semiconductor device to solve the aforementioned problems becomes an important issue to be solved by those in the industry.

### SUMMARY

An aspect of the disclosure is to provide a method of forming a semiconductor device that may efficiently solve the aforementioned problems.

According to an embodiment of the disclosure, a method of forming a semiconductor device includes forming a first metal material lining a trench in a semiconductor substrate at a first temperature. The method further includes forming a second metal material lining the first metal material at a second temperature higher than the first temperature. The method further includes performing an annealing process to the first and second metal materials.

In some embodiments, the first metal material is in contact with the semiconductor substrate and separates the second metal material from the semiconductor substrate.

In some embodiments, the first metal material and the second metal material fill the trench and extend over a top surface of the semiconductor substrate.

In some embodiments, the first metal material and the second metal material comprise a same material.

In some embodiments, the first metal material and the second metal material are made of a titanium-based material.

In some embodiments, the second metal material lining the first metal material is formed at the second temperature higher than the first temperature, such that a second grain size of the second metal material is greater than a first grain size of the first metal material.

In some embodiments, the annealing process is performed to recrystallize the first metal material and the second metal material to form a third metal material made out of a homogeneous material.

In some embodiments, the annealing process is performed at a third temperature higher than the first temperature and the second temperature.

In some embodiments, the first temperature and the second temperature are in a range from about 350˚C to about 550˚C, and the third temperature is in a range from about 500˚C to about 650˚C.

According to another embodiment of the disclosure, a method of forming a semiconductor device includes forming a gate dielectric layer lining a trench in a semiconductor substrate. The method further includes depositing a first gate material lining the gate dielectric layer at a first temperature. The method further includes depositing a second gate material lining the first gate material at a second temperature different from the first temperature. The method further includes performing an annealing process to recrystallize the first and second gate materials at a third temperature higher than the first temperature and the second temperature. After the annealing process is completed, a third gate material is formed.

In some embodiments, the first gate material and the second gate material comprise a same material but with different grain sizes.

In some embodiments, before performing the annealing process, a grain size of the second gate material is greater than a grain size of the first gate material.

In some embodiments, the first gate material and the second gate material are made of titanium nitride.

In some embodiments, the first temperature and the second temperature are in a range from about 350˚C to about 550˚C, and the third temperature is in a range from about 500˚C to about 650˚C.

In some embodiments, the first temperature is lower than the second temperature.

In some embodiments, the first temperature is in a range from about 350˚C to about 450˚C, and the second temperature is in a range from about 400˚C to about 550˚C.

In some embodiments, a deposition rate of the second gate material is higher than a deposition rate of the first gate material.

In some embodiments, the third gate material is made out of a homogeneous material.

In some embodiments, the method further includes etching back the third gate material such that a top surface of the third gate material is lower than a top surface of the semiconductor substrate.

In some embodiments, the third gate material serves as a word line. The method further includes forming a bit line and a capacitor electrically connected with doped regions in the semiconductor substrate and on opposite sides of the third gate material, respectively.

Accordingly, in the method of forming the semiconductor device of some embodiments of the present disclosure, by forming a first metal layer at a relatively low temperature and lining a trench of an underlying layer, residual stress between the first metal layer and the underlying layer may be reduced and thereby the phenomenon of line wiggling may be mitigated. Then, by forming a second metal layer at a relatively high temperature on the first metal layer, the formation of the second metal layer may be faster than that of the first metal layer, which accelerates the formation of the overall metal layer. In addition, the formed second metal layer may have a lower resistivity than the first metal layer. Hence, a more effective method of forming a semiconductor device with a lower resistivity may be accomplished.

It is to be understood that both the foregoing general description and the following detailed description are by examples, and are intended to provide further explanation of the invention as claimed.

### BRIEF DESCRIPTION OF THE DRAWINGS

The invention can be more fully understood by reading the following detailed description of the embodiment, with reference made to the accompanying drawings as follows:

FIG. 1 to FIG. 4 are cross-sectional views of intermediate stages of a method of forming a semiconductor device according to some embodiments of the present disclosure;

FIG. 5 is a circuit diagram of a memory cell of a semiconductor device formed by a method according to some other embodiments of the present disclosure;

FIG. 6 is a top view of a semiconductor device formed by a method according to some other embodiments of the present disclosure;

FIG. 7A, FIG. 7B, FIG. 8, FIG. 9, FIG. 10A, FIG. 10B, and FIG. 13 to FIG. 16 are cross-sectional views of intermediate stages of a method of forming a semiconductor device according to some other embodiments of the present disclosure; and

FIG. 11 and FIG. 12 are partial perspective views of intermediate stages of a method of forming a semiconductor device according to some other embodiments of the present disclosure.

### DETAILED DESCRIPTION

Reference will now be made in detail to the present embodiments of the invention, examples of which are illustrated in the accompanying drawings. Wherever possible, the same reference numbers are used in the drawings and the description to refer to the same or like parts.

As used herein, “around,” “about,” “approximately,” or “substantially” may generally mean within 20 percent, or within 10 percent, or within 5 percent of a given value or range. Numerical quantities given herein are approximate, meaning that the term “around,” “about,” “approximately,” or “substantially” can be inferred if not expressly stated.

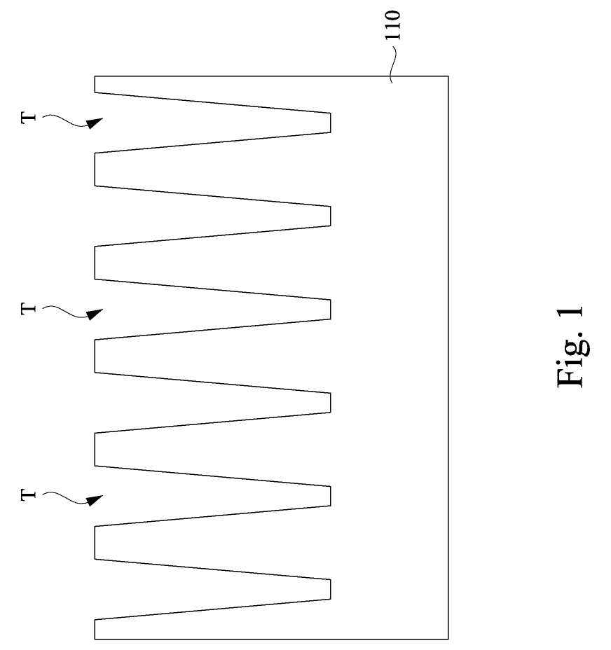

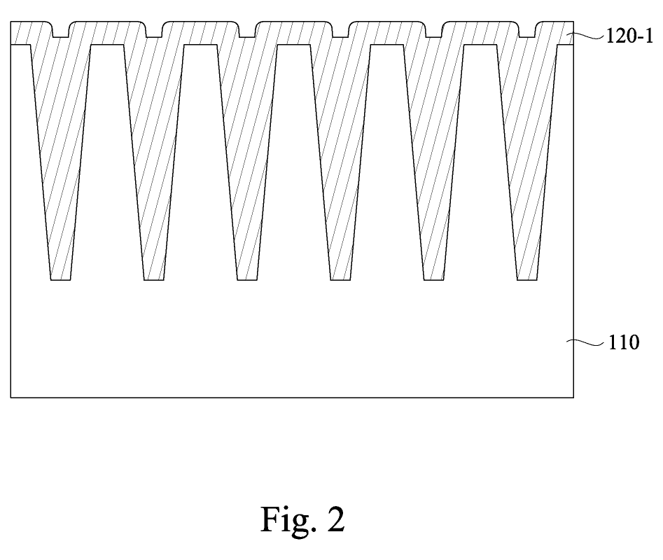

Reference is made to FIG. 1 to FIG. 4. FIG. 1 to FIG. 4 are cross-sectional views of intermediate stages of a method of forming a semiconductor device 10 according to some embodiments of the present disclosure.

Reference is first made to FIG. 1. A semiconductor substrate 110 is provided. A plurality of trenches T are formed in the semiconductor substrate 110. In some embodiments, the semiconductor substrate 110 may be formed of a silicon-containing material, such as silicon.

Reference is made to FIG. 2. A first metal material 120-1 is formed lining the trenches T in the semiconductor substrate 110. In some embodiments, the first metal material 120-1 may be formed of suitable material including metal, metal nitride, or a combination thereof. In some embodiments, the first metal material 120-1 may comprise a titanium-based material or a tantalum-based material, such as titanium, titanium nitride (TiN), tantalum, or tantalum nitride (TaN).

As shown in FIG. 2, the first metal material 120-1 may be in contact with the semiconductor substrate 110. In such embodiments, residual stress may exist at the interface between the first metal material 120-1 and the semiconductor substrate 110, which may cause line wiggling and deteriorates the performance of the resultant semiconductor device 10. Accordingly, in some embodiments, the first metal material 120-1 may be formed at a first temperature in a range from about 350˚C to about 450˚C to reduce the residual stress at the interface. As such, profiles of the trenches T may be reinforced by the low-stress metal layer, which helps mitigate line wiggling problems.

In addition, in some embodiments, the first metal material 120-1 may be formed fully filling the trenches T to further improve the structural strength. For example, as shown in FIG. 2, a top surface of the first metal material 120-1 may be at least higher than a top surface of the semiconductor substrate 110.

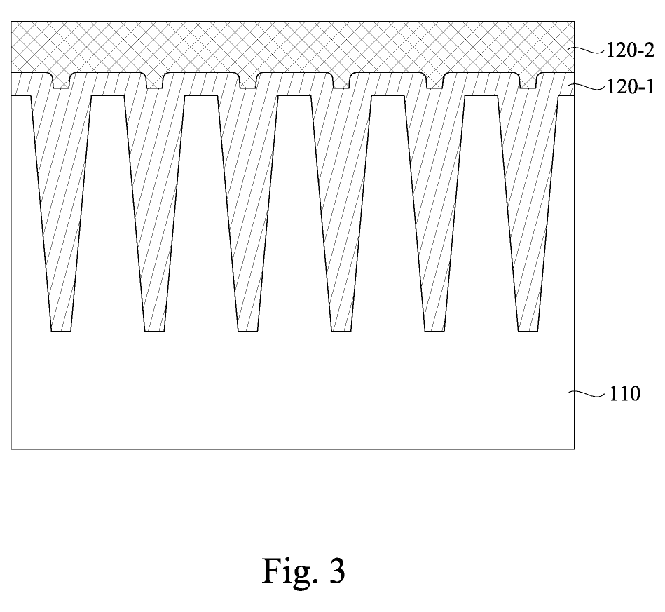

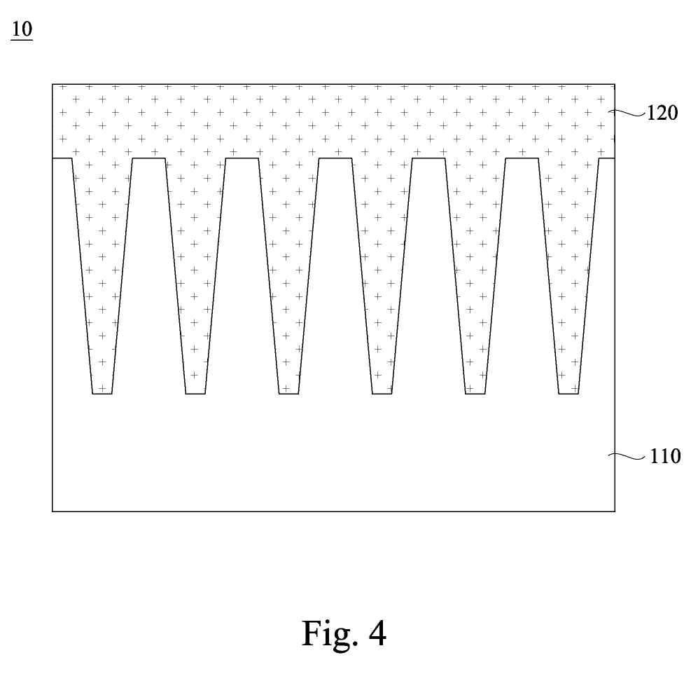

Reference is made to FIG. 3. A second metal material 120-2 is then formed lining the first metal material 120-1. In some embodiments, the first metal material 120-1 and the second metal material 120-2 together fill the trenches T and extend over the top surface of the semiconductor substrate 110. Similarly, in some embodiments, the second metal material 120-2 may be formed of suitable material including metal, metal nitride, or a combination thereof. In some embodiments, the second metal material 120-2 may comprise a titanium-based material or a tantalum-based material, such as titanium, titanium nitride, tantalum, or tantalum nitride.

Furthermore, in some embodiments, the first metal material 120-1 and the second metal material 120-2 may be made of a same material. For example, according to an exemplary embodiment of the present disclosure, the first metal material 120-1 and the second metal material 120-2 are made of titanium nitride. In some other embodiments, the first metal material 120-1 and the second metal material 120-2 may be made of different materials.

In the step corresponding to FIG. 3, the second metal material 120-2 is formed at a second temperature different from the first temperature for forming the first metal material 120-1. In the exemplary embodiment, the first metal material 120-1 and the second metal material 120-2 are both made of titanium nitride. Therefore, the second temperature may be deliberately chosen to modify the overall properties of the metal materials and to optimize the fabrication processes.

First, process time is related to the temperature. For example, deposition time of a titanium nitride layer decreases as the deposition temperature increases. Therefore, in the exemplary embodiment, the second temperature for forming the second metal material 120-2 may be set higher than the first temperature for forming the first metal material 120-1 to reduce the overall process time.

Second, grain size of the metal material is also related to the temperature. For example, the grain size of a deposited titanium nitride layer increases as the deposition temperature increases. An increase in grain size may reduce the number of scattered electrons at grain boundaries of the deposited titanium nitride layer, thereby reducing the resistivity of the deposited titanium nitride layer. Therefore, in the exemplary embodiment, the second temperature for forming the second metal material 120-2 may be set higher than the first temperature for forming the first metal material 120-1 such that a second grain size of the second metal material 120-2 is greater than a first grain size of the first metal material 120-1. Accordingly, the second metal material 120-2 presents a lower resistivity than the first metal material 120-1. In greater detail, the second temperature may be in a range from about 400˚C to about 550˚C.

As shown in FIG. 3, in some embodiments, the second metal material 120-2 is spaced apart from the semiconductor substrate 110 through the first metal material 120-1. As such, the relatively high residual stress of the second metal material 120-2 due to the relatively high process temperature may not be transferred to the semiconductor substrate 110. Further, in some embodiments, the second metal material 120-2 is disposed completely over the top surface of the semiconductor substrate 110.

Reference is then made to FIG. 4. An annealing process is performed to the first metal material 120-1 and the second metal material 120-2 to form a third metal material 120 made out of a homogeneous material. In some embodiments, the annealing process is performed at a third temperature higher than the first temperature and the second temperature. To be more specific, the first temperature and the second temperature are in a range from about 350˚C to about 550˚C, and the third temperature is in a range from about 500˚C to about 650˚C.

As shown in FIG. 4, after the annealing process, an interface between the first metal material 120-1 and the second metal material 120-2 is eliminated or becomes indistinct due to recrystallization and crystal growth. For example, the grain size of the first metal material 120-1 and the grain size of the second metal material 120-2 increases and are substantially the same size after the annealing process. Moreover, since the grain size of the resultant third metal material 120 is greater than the first and second grain sizes, the resultant third metal material 120 presents a lower resistivity than the first metal material 120-1 and the second metal material 120-2.

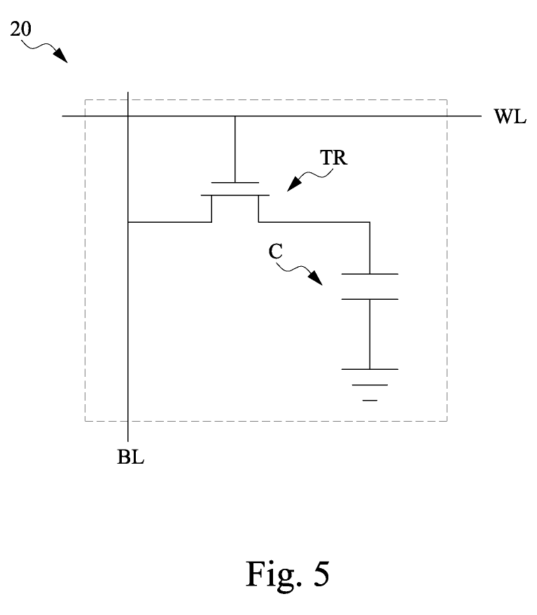

Reference is now made to FIG. 5. FIG. 5 is a circuit diagram of a memory cell of a semiconductor device 20 formed by a method according to some other embodiments of the present disclosure. In some embodiments, the semiconductor device 20 is a dynamic random access memory (DRAM) device. The semiconductor device 20 has a plurality of memory cells. Each memory cell of the semiconductor device 20 includes a transistor TR and a capacitor C as main structures, as shown in FIG. 5. One side of capacitor C is coupled with a drain region of the transistor TR. The other side of the capacitor C is coupled to the ground. The semiconductor device 20 further includes a word line WL coupled with a gate region of the transistor TR and a bit line BL coupled with a source region of the transistor TR. The operation of the semiconductor device 20 can be achieved by utilization of the word line WL and the bit line BL, and the storage of data can be accomplished by controlling the charges in the capacitor C. The charge transportation over the capacitor C can be determined by the control of the transistor TR, which may be manipulated by the bit line BL and the word line WL to characterize the reading and writing of the signal.

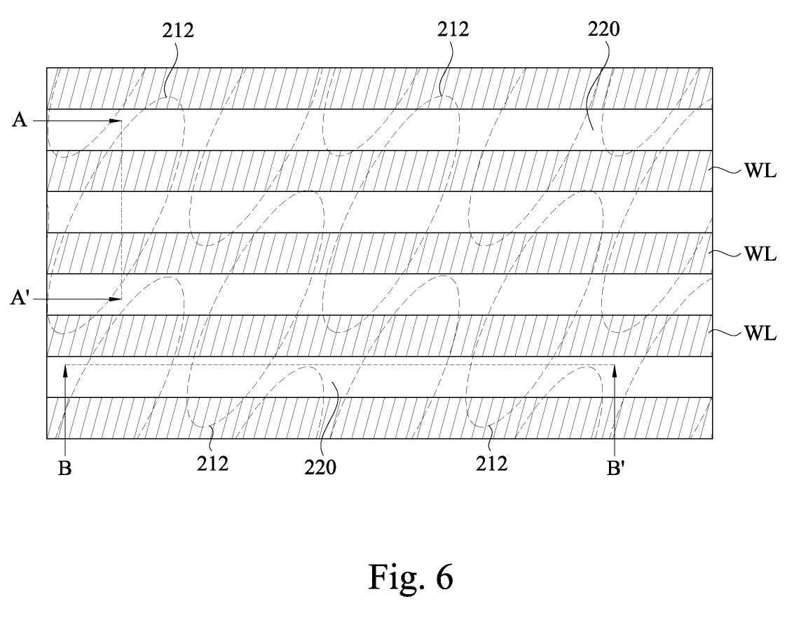

Reference is then made to FIG. 6. FIG. 6 illustrates a top view of the semiconductor device 20 formed by the method according to some other embodiments of the present disclosure. It should be noted that FIG. 6 only illustrates some of the components of the semiconductor device 20, and other components are omitted for simplicity. As shown in FIG. 6, the semiconductor device 20 includes a plurality of isolation structures 220. The regions not covered by the isolation structures 220 may be referred to as active areas 212. The semiconductor device 20 further includes a plurality of word lines WL across the active areas 212. The word lines WL are in parallel to each other. Additionally, the word lines WL may be spaced apart from each other at substantially equal intervals.

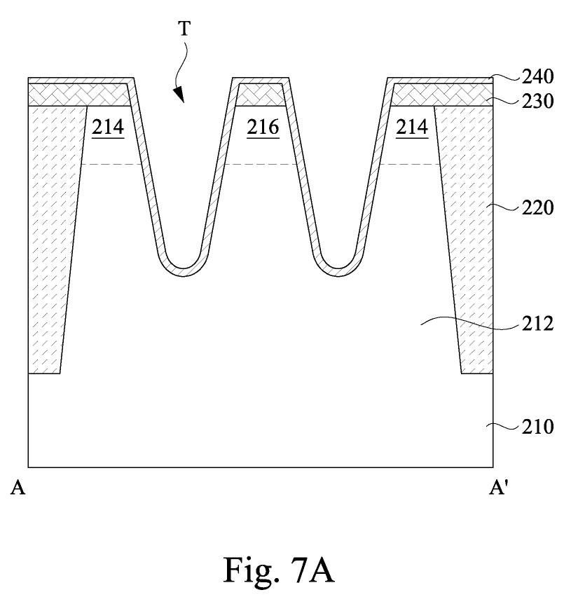

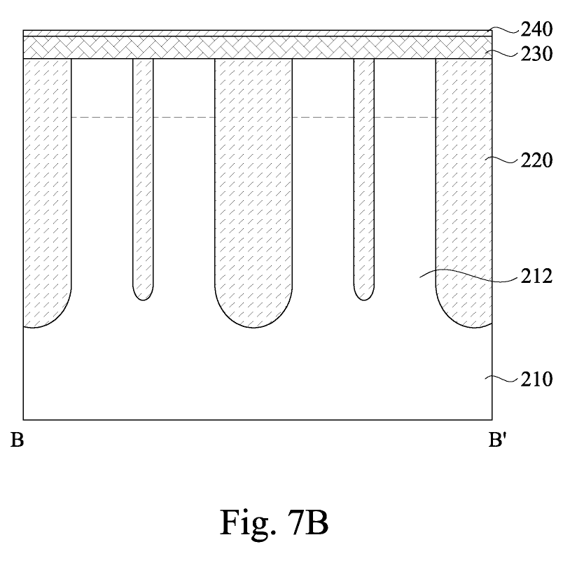

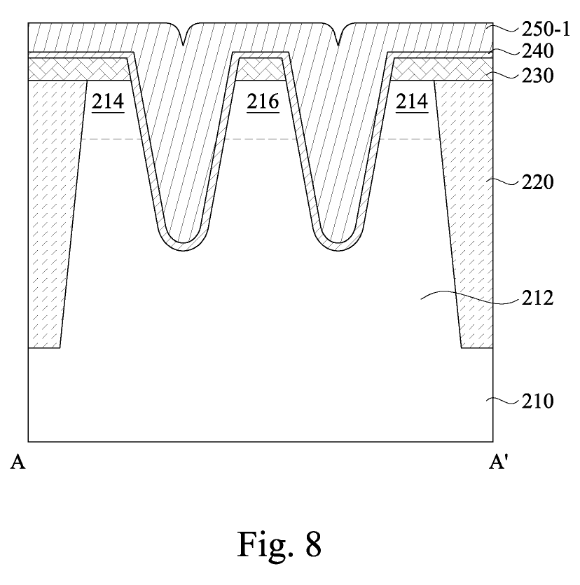

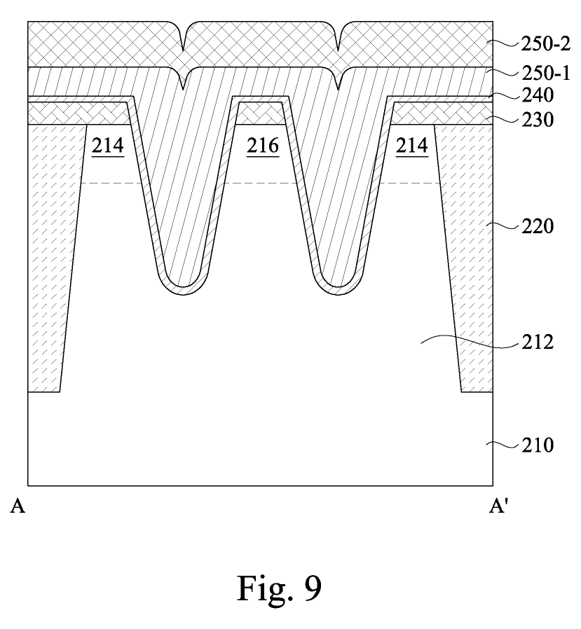

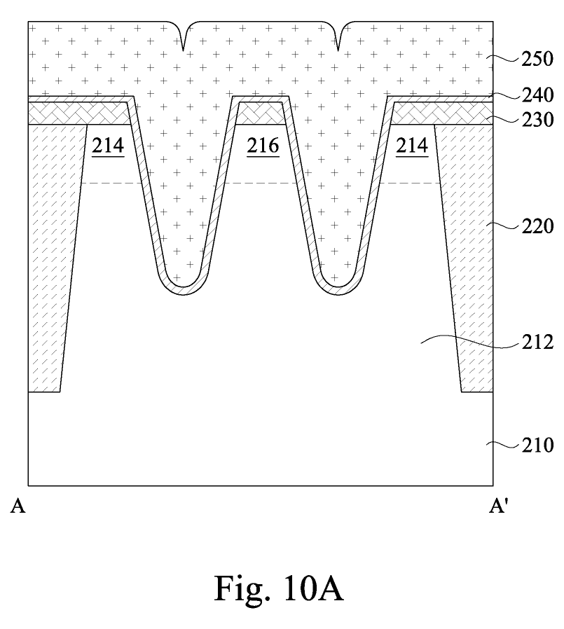

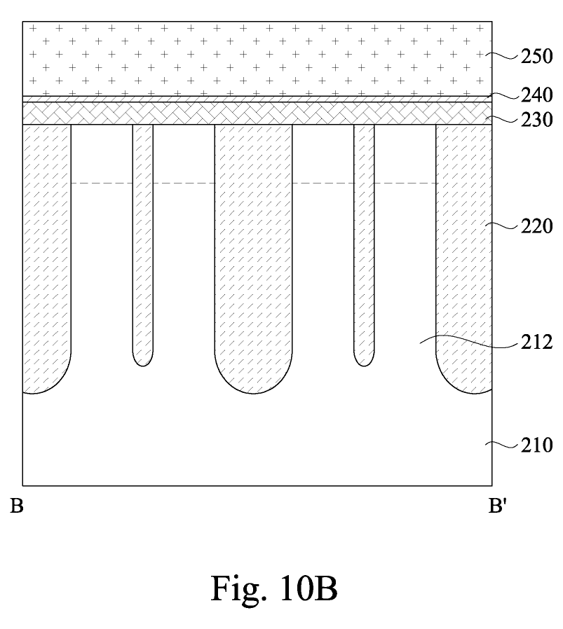

FIG. 7A, FIG. 7B, FIG. 8, FIG. 9, FIG. 10A, and FIG. 10B are cross-sectional views of intermediate stages of a method of forming the semiconductor device 20 according to some other embodiments of the present disclosure. FIG. 7A, FIG. 8, FIG. 9, and FIG. 10A are cross-sectional views taken along line A-A’ in FIG. 6. FIG. 7B and FIG. 10B are cross-sectional views taken along line B-B’ in FIG. 6.

Reference is now made to FIG. 7A and FIG. 7B. A semiconductor substrate 210 is firstly provided. In some embodiments, the semiconductor substrate 210 may be formed of a silicon-containing material, such as silicon. In some other embodiments, the semiconductor substrate 210 may include a Silicon-On-Insulator (SOI) substrate.

As shown in FIG. 7A and FIG. 7B, the semiconductor substrate 210 includes isolation structures 220 and an active area 212. The isolation structures 220 may be any suitable isolation structures, such as shallow trench isolation (STI) structures. The active area 212 may be referred as to a channel region of a transistor (e.g., the transistor TR shown in FIG. 5). In some embodiments, the isolation structures 220 may be made of dielectric materials, such as silicon oxide, silicon nitride, or a combination thereof.

The active area 212 of the semiconductor substrate 210 may include doped regions. For example, as shown in FIG. 7A, a pair of doped regions including one drain region 214 and one source region 216 are disposed on opposite sides of each trench T, respectively. In some embodiments, the doped regions may include opposite conductivity type than the semiconductor substrate 210. For example, when the semiconductor substrate 210 is a p-type substrate, the doped regions may be n-type doped regions. Similarly, when the semiconductor substrate 210 is an n-type substrate, the doped regions may be p-type doped regions. In some embodiments, the bottom surfaces of the doping regions may be positioned at a predetermined level from the top surface of the active area 212.

As shown in FIG. 7A and FIG. 7B, a dielectric layer 230 may be formed on a top surface of the semiconductor substrate 210. In some embodiments, the dielectric layer 230 may comprise dielectric materials, such as nitride.

Then, trenches T are formed extending through the dielectric layer 230 into the active area 212 of the semiconductor substrate 210, as shown in FIG. 7A and FIG. 7B. In some embodiments, the bottom edges of the trenches T may have a round shape and then the shape of the trenches T may be formed in a U shape. In some other embodiments, the bottom edges of the trenches T may be substantially flat.

Subsequently, as shown in FIG. 7A and FIG. 7B, a gate dielectric layer 240 is formed lining the trenches T. In some embodiments, the gate dielectric layer 240 may comprise dielectric materials, such as oxide. In some embodiment, the gate dielectric layer 240 may be formed by depositing a dielectric material conformally covering inner sidewalls of the trenches T and top surfaces of the isolation structures 220 and the active area 212. In some other embodiments, the gate dielectric layer 240 may be formed by thermal oxidation. In such embodiments, the gate dielectric layer 240 may not extend over the top surfaces of the isolation structures 220 and the active area 212.

Reference is then made to FIG. 8. A first gate material 250-1 is deposited lining the gate dielectric layer 240. In some embodiments, the first gate material 250-1 may be formed of any suitable material including metal, metal nitride, or a combination thereof. In some embodiments, the first gate material 250-1 may comprise a titanium-based material or a tantalum-based material, such as titanium, titanium nitride, tantalum, or tantalum nitride.

As shown in FIG. 8, the first gate material 250-1 may be in contact with the gate dielectric layer 240. Similarly, residual stress may exist at the interface between the first gate material 250-1 and the gate dielectric layer 240, which may induce the phenomenon of line wiggling. Accordingly, in some embodiments, the first gate material 250-1 may be formed at a first temperature in a range from about 350˚C to about 450˚C so that the first gate material 250-1 has relatively low residual stress and thereby helps avoid accumulation of the residual stress at the interface.

In addition, as shown in FIG. 8, in some embodiments, the first gate material 250-1 may be formed fully filling the trenches T to further reinforce the structure of the trenches T. For example, a top surface of the first gate material 250-1 may be at least higher than the top surface of the semiconductor substrate 210. Moreover, as shown in FIG. 8, some recesses may exist on a top surface of the first gate material 250-1.

Reference is then made to FIG. 9. A second gate material 250-2 is deposited lining the first gate material 250-1. Similarly, in some embodiments, the second gate material 250-2 may be formed of any suitable material including metal, metal nitride, or a combination thereof. In some embodiments, the second gate material 250-2 may comprise a titanium-based material or a tantalum-based material, such as titanium, titanium nitride, tantalum, or tantalum nitride. Similarly, in some embodiments, the first gate material 250-1 and the second gate material 250-2 may comprise a same material. For example, according to an exemplary embodiment of the present disclosure, the first gate material 250-1 and the second gate material 250-2 are made of titanium nitride.

Besides, in the step corresponding to FIG. 9, the second gate material 250-2 is formed at a second temperature different from the first temperature. Since in the exemplary embodiment, both the first gate material 250-1 and the second gate material 250-2 are made of titanium nitride, the second temperature may be deliberately chosen to achieve certain properties of the resultant semiconductor device and accomplish process optimization. For example, in the exemplary embodiment, the second temperature may be set higher than the first temperature. To be more specific, the second temperature may be in a range from about 400˚C to about 550˚C. For example, the second temperature may be about 475˚C. As such, a second grain size of the second gate material 250-2 is greater than a first grain size of the first gate material 250-1, and thereby the second gate material 250-2 presents a lower resistivity than the first gate material 250-1. Meanwhile, a deposition rate of the second gate material 250-2 is higher than a deposition rate of the first gate material 250-1. In other words, for a certain thickness of the gate materials, depositing firstly the first gate material 250-1 at a lower first temperature and then depositing the second gate material 250-2 at a higher second temperature takes less process time than depositing at the lower first temperature throughout the deposition of the gate materials.

Reference is then made to FIG. 10A and FIG. 10B. An annealing process is performed to the first gate material 250-1 and the second gate material 250-2 to form a third gate material 250 after the annealing process is completed. The third gate material 250 is made out of a homogeneous material. In greater detail, the third gate material 250 has a uniform grain size distribution. In other words, after the annealing process, the grain size of the first metal material 120-1 and the grain size of the second metal material 120-2 increases and are substantially the same size due to recrystallization and crystal growth, and thus an interface between the first gate material 250-1 and the second gate material 250-2 is eliminated or becomes indistinct.

In some embodiments, the annealing process is performed at a third temperature higher than the first temperature and the second temperature. To be more specific, the first temperature and the second temperature are in a range from about 350˚C to about 550˚C, and the third temperature is in a range from about 500˚C to about 650˚C. In the exemplary embodiment, the second temperature for forming the second gate material 250-2 may be about 475˚C. Then, the first temperature for forming the first gate material 250-1 may be about 400˚C or about 410˚C, and the third temperature for annealing may be about 525˚C or 600˚C.

In some embodiments, an annealing time of the annealing process may be about 20 minutes. As such, in the exemplary embodiment above, the process time of forming the third gate material 250 may be in a range from about 6 hour to about 6 hour 30 minutes. Here, the term “process time of forming the third gate material 250” may be the sum of the process time of depositing the first gate material 250-1, the process time of depositing the second gate material 250-2, and the process time of the annealing process.

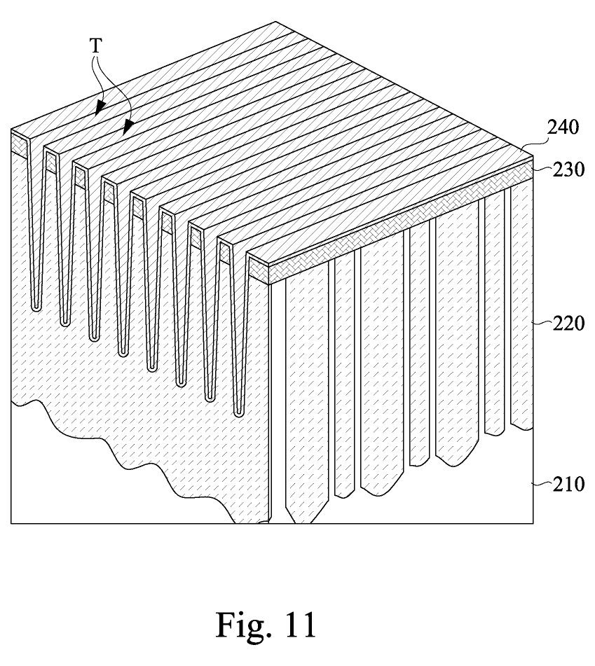

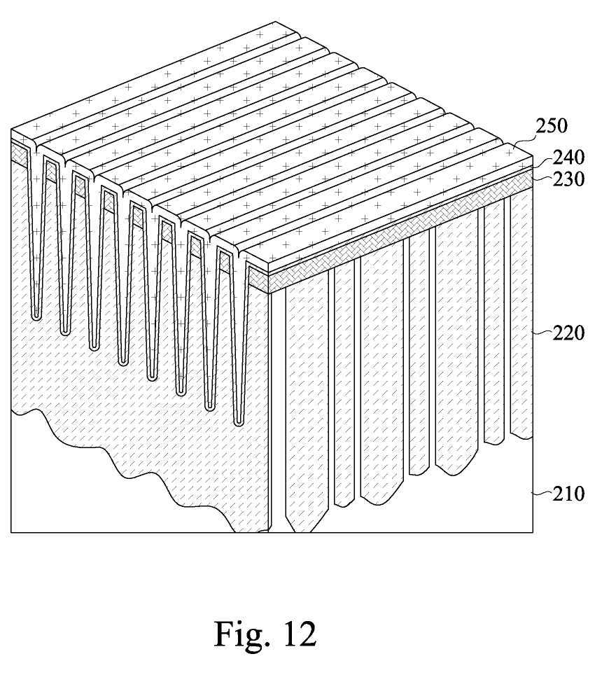

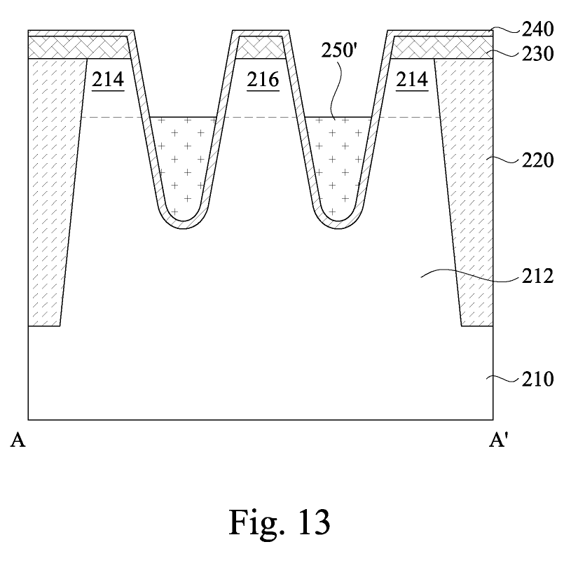

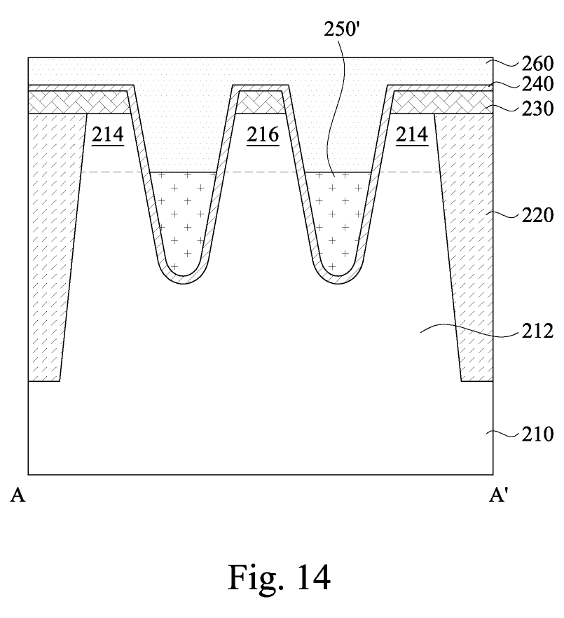

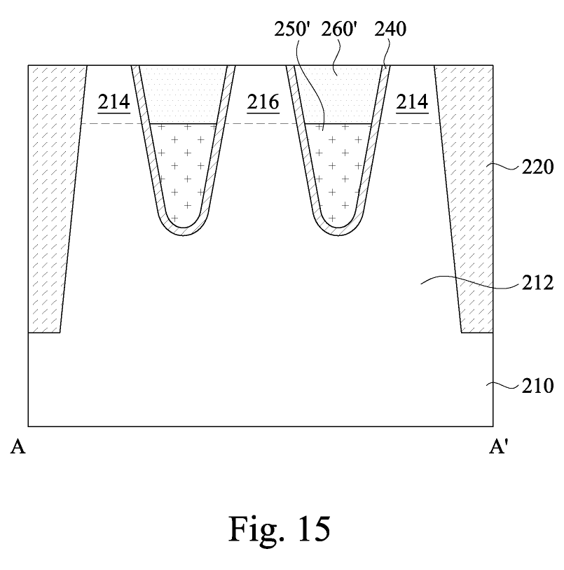

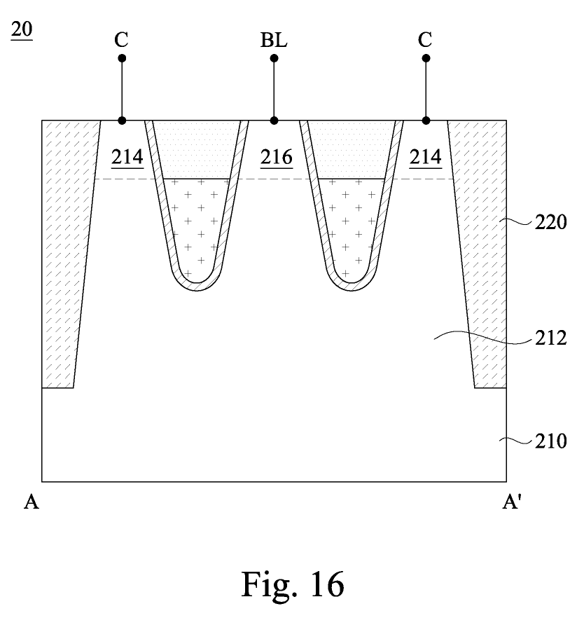

Reference is then made to FIG. 11 and FIG. 12. FIG. 11 and FIG. 12 are partial perspective views of intermediate stages of the method of forming the semiconductor device 20. First, the stage of FIG. 11 corresponds to the stage of FIG. 7A and FIG. 7B. As shown in FIG. 11, the gate dielectric layer 240 is formed lining the trenches T in the semiconductor substrate 210. Second, the stage of FIG. 12 corresponds to the stage of FIG. 10A and FIG. 10B. As shown in FIG. 12, after the annealing process, the resultant third gate material 250 is disposed fully filling the trenches T and extending over a top surface of the gate dielectric layer 240.

Reference is made to FIG. 13 to FIG. 16 for further details. FIG. 13 to FIG. 16 are cross-sectional views of intermediate stages of the method of forming the semiconductor device 20 and are taken along line A-A’ in FIG. 6.

As shown in FIG. 13, the third gate material 250 is etched back such that top surfaces of the etched third gate material are lower than the top surface of the semiconductor substrate 210. The etched third gate material may then be referred to as gate electrodes 250’.

Next, as shown in FIG. 14, a dielectric material 260 is formed covering the top surfaces of the gate electrodes 250’ and the gate dielectric layer 240. In some embodiments, the dielectric material 260 may include silicon nitride, silicon oxide, or a combination thereof. In some embodiments, the dielectric material 260 may be formed by spin-on dielectric (SOD) deposition.

Then, as shown in FIG. 15, a planarization process, such as CMP, is performed to remove portions of the dielectric layer 230, the gate dielectric layer 240, and the dielectric material 260 to expose the top surfaces of the isolation structures 220 and the active area 212. The remaining dielectric material may be referred to as cap layers 260’. As shown in FIG. 15, top surfaces of the cap layers 260’ are substantially level with the top surfaces of the isolation structures 220 and the active area 212.

Reference is made to FIG. 16. Bit lines BL and capacitors C are formed electrically connected with the doped regions in the semiconductor substrate 210. For example, one capacitor C is electrically connected with the drain region 214, and one bit line BL is electrically connected with the source region 216.

The structure shown in FIG. 16 is an exemplary structure of the semiconductor device 20 shown in FIG. 5. For example, the gate electrode 250’, the gate dielectric layer 240, the drain region 214 and the source region 216 on opposite sides of the gate electrode 250’, and the active area 212 of the semiconductor substrate 201 may collective serve as the transistor of the semiconductor device 20 (e.g. the transistor TR of FIG. 5). In greater detail, the gate electrode 250’ may also serve as the word line of the semiconductor device 20 (e.g. the word line WL of FIG. 5). The capacitor C is electrically connected with the drain region 214 of the transistor, and the bit line BL is electrically connected with the source region 216 of the transistor.

According to the foregoing recitations of the embodiments of the disclosure, it may be seen that in the method of forming the semiconductor device of some embodiments of the present disclosure, by forming a first metal layer at a relatively low temperature and lining a trench of an underlying layer, residual stress between the first metal layer and the underlying layer may be reduced and thereby the phenomenon of line wiggling may be mitigated. Then, by forming a second metal layer at a relatively high temperature on the first metal layer, the formation of the second metal layer may be faster than that of the first metal layer, which accelerates the formation of the overall metal layer. In addition, the formed second metal layer may have a lower resistivity than the first metal layer. Hence, a more effective method of forming a semiconductor device with a lower resistivity may be accomplished.

Although the present invention has been described in considerable detail with reference to certain embodiments thereof, other embodiments are possible. Therefore, the spirit and scope of the appended claims should not be limited to the description of the embodiments contained herein.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims.

What is claimed is:

1. A method of forming a semiconductor device, comprising:
forming a first metal material lining a trench in a semiconductor substrate at a first temperature;
forming a second metal material lining the first metal material at a second temperature higher than the first temperature; and
performing an annealing process to the first and second metal materials.

2. The method of claim 1, wherein the first metal material is in contact with the semiconductor substrate and separates the second metal material from the semiconductor substrate.

3. The method of claim 1, wherein the first metal material and the second metal material fill the trench and extend over a top surface of the semiconductor substrate.

4. The method of claim 1, wherein the first metal material and the second metal material comprise a same material.

5. The method of claim 1, wherein the first metal material and the second metal material are made of a titanium-based material.

6. The method of claim 1, wherein the second metal material lining the first metal material is formed at the second temperature higher than the first temperature, such that a second grain size of the second metal material is greater than a first grain size of the first metal material.

7. The method of claim 6, wherein the annealing process is performed to recrystallize the first metal material and the second metal material to form a third metal material made out of a homogeneous material.

8. The method of claim 1, wherein the annealing process is performed at a third temperature higher than the first temperature and the second temperature.

9. The method of claim 8, wherein the first temperature and the second temperature are in a range from about 350˚C to about 550˚C, and the third temperature is in a range from about 500˚C to about 650˚C.

10. A method of forming a semiconductor device, comprising:
forming a gate dielectric layer lining a trench in a semiconductor substrate;
depositing a first gate material lining the gate dielectric layer at a first temperature;
depositing a second gate material lining the first gate material at a second temperature different from the first temperature; and
performing an annealing process to recrystallize the first and second gate materials at a third temperature higher than the first temperature and the second temperature, wherein after the annealing process is completed, a third gate material is formed.

11. The method of claim 10, wherein the first gate material and the second gate material comprise a same material but with different grain sizes.

12. The method of claim 11, wherein before performing the annealing process, a grain size of the second gate material is greater than a grain size of the first gate material.

13. The method of claim 10, wherein the first gate material and the second gate material are made of titanium nitride.

14. The method of claim 10, wherein the first temperature and the second temperature are in a range from about 350˚C to about 550˚C, and the third temperature is in a range from about 500˚C to about 650˚C.

15. The method of claim 14, wherein the first temperature is lower than the second temperature.

16. The method of claim 14, wherein the first temperature is in a range from about 350˚C to about 450˚C, and the second temperature is in a range from about 400˚C to about 550˚C.

17. The method of claim 10, wherein a deposition rate of the second gate material is higher than a deposition rate of the first gate material.

18. The method of claim 10, wherein the third gate material is made out of a homogeneous material.

19. The method of claim 10, further comprising etching back the third gate material such that a top surface of the third gate material is lower than a top surface of the semiconductor substrate.

20. The method of claim 10, wherein the third gate material serves as a word line, and the method further comprising:
forming a bit line and a capacitor electrically connected with doped regions in the semiconductor substrate and on opposite sides of the third gate material, respectively.
